(19) United States
(12) Patent Application Publication
(10) Pub. No.: US 2024/0067041 A1
(43) Pub. Date: Feb. 29, 2024

(54) PORTABLE BATTERY DEVICE FOR A MOBILITY APPARATUS AND A BATTERY MANAGEMENT SYSTEM AND METHOD FOR A MOBILITY APPARATUS

(71) Applicants: HYUNDAI MOTOR COMPANY, Seoul (KR); KIA CORPORATION, Seoul (KR)

(72) Inventors: Hong Heui Lee, Suwon-si (KR); Dong Eun Cha, Hwaseong-si (KR); Jin Young Yoon, Gimpo-si (KR)

(73) Assignees: HYUNDAI MOTOR COMPANY, Seoul (KR); KIA CORPORATION, Seoul (KR)

(21) Appl. No.: 18/076,838

(22) Filed: Dec. 7, 2022

(30) Foreign Application Priority Data
Aug. 31, 2022 (KR) 10-2022-0109975

(51) Int. Cl. B60L 58/12; B60L 53/16; B60L 58/18; G01R 31/387; H01M 10/42; H01M 10/48; H01M 50/242; H01M 50/249; H01M 50/298

(52) U.S. Cl. CPC B60L 58/12; B60L 53/16; B60L 58/18; G01R 31/387; H01M 10/425; H01M 10/48; H01M 50/242; H01M 50/249; H01M 50/298; H01M 2010/4271; H01M 2220/20

(57) ABSTRACT

A portable battery device for a mobility apparatus and a battery management system and a method, which are capable of securing a desired range of the mobility apparatus by selectively adding an auxiliary battery in a situation in which a battery capacity should be additionally supplemented, are disclosed. The auxiliary battery is stored in the mobility apparatus or is supplied from an external supply source when the auxiliary battery is commercially available. Accordingly, electric power supply to the mobility apparatus becomes convenient. The auxiliary battery is simply replaceable through separation or mounting thereof from or in a case at an outside of the mobility apparatus. Accordingly, handling convenience of the auxiliary battery is enhanced. When collision of the mobility apparatus occurs, the auxiliary battery is separated due to impact and, as such, generation of fire caused by damage to the auxiliary battery is prevented and stability is secured.

### CROSS-REFERENCE TO RELATED APPLICATION

This application claims the benefit of priority to Korean Patent Application No. 10-2022-0109975, filed on Aug. 31, 2022, in the Korean Intellectual Property Office, the disclosure of which is incorporated herein for all purposes by reference.

### BACKGROUND

### 1. Field

The present disclosure relates to a portable battery device for a mobility apparatus and a battery management system and a method for a mobility apparatus that are capable of securing a desired range of a mobility apparatus driven by electric power and enhancing battery management convenience.

### 2. Description of the Related Art

Recently, realization of eco-friendly technologies and solutions of problems such as exhaustion of energy and the like have become social issues. To overcome these issues, an electric vehicle has been developed. The electric vehicle is driven using a motor configured to receive electricity from a battery, thereby outputting power. In this regard, the electric vehicle is being highlighted as an eco-friendly vehicle by virtue of advantages of no emission of carbon dioxide, reduced noise, and higher energy efficiency of the motor than that of an engine.

A core technology for implementation of such an electric vehicle is a technology associated with a battery module. Recently, active research on lightness, miniaturization, reduced recharging time, and the like, of a battery has been conducted.

The electric vehicle secures a desired range through advances in battery technology and fuel efficiency technology. In addition, the electric vehicle should require battery recharging in which a certain charging time is taken, and a recharging station should be placed within a driving range of the electric vehicle. Only when such requirements are satisfied, may the electric vehicle cope with various driving situations including long distance travel.

However, the electric vehicle has a limited range in accordance with specifications of a battery thereof. When battery power is completely consumed during driving, there is no method of recharging the battery. The only means of settling this problem is to tow the electric vehicle.

Therefore, a scheme for securing an increased range of the electric vehicle through an improvement in the recharging method, a reduction in the recharging time, and the like, is required.

The above matters disclosed in this section are merely for enhancement of understanding of the general background of the disclosure and should not be taken as an acknowledgement or any form of suggestion that the matters form the related art already known to a person of ordinary skill in the art.

### SUMMARY

Therefore, the present disclosure has been made in view of the above problems. It is an objective of the present disclosure to provide a portable battery device for a mobility apparatus and a battery management system and a method for a mobility apparatus that are capable of securing a desired range of a mobility apparatus driven by electric power and enhancing battery management convenience.

In accordance with an aspect of the present disclosure, the above and other objectives can be accomplished by the provision of a portable battery device for a mobility apparatus including: a high-voltage battery equipped in the mobility apparatus; a case provided in an inner space of the mobility apparatus and formed to receive an auxiliary battery therein, such that the auxiliary battery is cradled; and a first wiring configured to electrically interconnect the high-voltage battery and the auxiliary battery received in the case.

The case may be installed in an inner space of a front part of the mobility apparatus.

A guard may be configured at a front part of the mobility apparatus. A first opening open to the inner space of the mobility apparatus may be formed at the guard. The case may be inserted into the guard through the first opening, for installation thereof. In other words, the case may be configured to be installed by being inserted into the guard through the first opening.

An isolation door selectively opening and closing the first opening in accordance with a moved position thereof may be installed at the guard.

A breakage inducing bracket configured to be broken upon receiving external force higher than a critical value may be provided at the first opening of the guard. The case may be installed at the guard by the breakage inducing bracket.

A plurality of breakage inducing slits may be formed along an edge of the breakage inducing bracket such that the breakage inducing slits are uniformly spaced apart from one another.

A second opening may be formed at the guard such that the second opening is open to the inner space of the mobility apparatus while being spaced apart from the first opening. A second wiring extending from the high-voltage battery may be installed at the second opening of the guard.

A charging door selectively opening and closing the second opening in accordance with a moved position thereof may be installed at the guard, and the charging door may be manually openable and closable.

A reception space may be configured at a front part of the mobility apparatus. The case may be installed in the reception space.

In accordance with another aspect of the present disclosure, there is provided a battery management method for a mobility apparatus including: primarily checking a state of charge (SOC) of a high-voltage battery; secondarily checking an electric power consumption amount of the high-voltage battery for travel from a start point to an arrival point, based on map information; deriving an electric power amount required for travel to the arrival point when travel to the arrival point is impossible using the checked electric power consumption amount of the high-voltage battery; and calculating a required number of auxiliary batteries in accordance with the derived required electric power amount.

The secondarily checking may check information as to a position where supply of an auxiliary battery is possible between the start point and the arrival point. The calculating may provide, to a passenger of the mobility apparatus, the information as to the position where supply of the auxiliary battery is possible.

In the portable battery device for the mobility apparatus and the battery management system and the method configured as described above, it may be possible to secure a desired range of the mobility apparatus by selectively adding an auxiliary battery in a situation in which a battery capacity should be additionally supplemented, for example, an emergency situation, a range required situation, or the like.

In addition, the auxiliary battery may be stored in the mobility apparatus or may be supplied from an external supply source when the auxiliary battery is commercially available. Accordingly, electric power supply to the mobility apparatus becomes convenient.

Furthermore, the auxiliary battery is simply replaceable through separation or mounting thereof from or in the case at an outside of the mobility apparatus. Accordingly, handling convenience of the auxiliary battery is enhanced.

In addition, when collision of the mobility apparatus occurs, the auxiliary battery is separated due to impact and, as such, generation of fire caused by damage to the auxiliary battery is prevented. Thus, stability is secured.

### BRIEF DESCRIPTION OF THE DRAWINGS

The above and other objectives, features and other advantages of the present disclosure should be more clearly understood from the following detailed description taken in conjunction with the accompanying drawings, in which:

FIG. 1 is a view showing a front part of a mobility apparatus according to an embodiment of the present disclosure;

FIG. 2 is a view showing an interior of the mobility apparatus shown in FIG. 1;

FIG. 3 is a view showing a portable battery device for the mobility apparatus according to an embodiment of the present disclosure;

FIG. 4 is a view showing a breakage inducing bracket in the portable battery device for the mobility apparatus shown in FIG. 3;

FIG. 5 is a view showing a portable battery device for a mobility apparatus according to another embodiment of the present disclosure;

FIG. 6 is a block diagram of a battery management system according to an embodiment of the present disclosure; and

FIG. 7 is a flowchart of a battery management method according to an embodiment of the present disclosure.

### DETAILED DESCRIPTION

Hereinafter, embodiments of the present disclosure are described in detail with reference to the accompanying drawings. the same or similar elements are designated by the same reference numerals regardless of the numerals in the drawings. Redundant descriptions thereof are omitted.

The suffixes “module” and “unit” of elements herein are used for convenience of description and thus can be used interchangeably and do not have any distinguishable meanings or functions.

In the following description of embodiments of the present disclosure, a detailed description of known functions and configurations incorporated herein is omitted when it may obscure the subject matter of embodiments of the present disclosure. In addition, embodiments of the present disclosure should be more clearly understood from the accompanying drawings and should not be limited by the accompanying drawings. It should be appreciated that all changes, equivalents, and substitutes that do not depart from the spirit and technical scope of the present disclosure are encompassed in the present disclosure.

It should be understood that, although the terms “first,” “second,” and the like, may be used herein to describe various elements, these elements should not be limited by these terms. These terms are only used to distinguish one element from another.

When an element is “connected” or “linked” to another element, it should be understood that the element may be directly connected or linked to the other element, or another element may be present therebetween. Conversely, when an element is “directly connected” or “directly linked” to another element, it should be understood that no other element is present therebetween.

Unless clearly used otherwise, singular expressions include a plural meaning.

In this specification, the term “comprising,” “including,” and the like, are intended to express the existence of a characteristic, a numeral, a step, an operation, an element, a part, or a combination thereof, and do not exclude another characteristic, numeral, step, operation, element, part, or any combination thereof, or any addition thereto.

A controller, according to an embodiment of the present disclosure, may be embodied through: a non-volatile memory (not shown) configured to store an algorithm configured to control operation of various constituent elements of a vehicle or data as to software commands for execution of the algorithm; and a processor (not shown) configured to execute operation, as is described hereinafter, using the data stored in the memory. The memory and the processor may be embodied as individual chips, respectively. Alternatively, the memory and the processor may be embodied as a single unified chip. The processor may take the form of one or more processors.

When a component, device, element, or the like of the present disclosure is described as having a purpose or performing an operation, function, or the like, the component, device, or element should be considered herein as being “configured to” meet that purpose or to perform that operation or function.

Hereinafter, a portable battery device for a mobility apparatus and a battery management system and a method according to embodiments of the present disclosure are described.

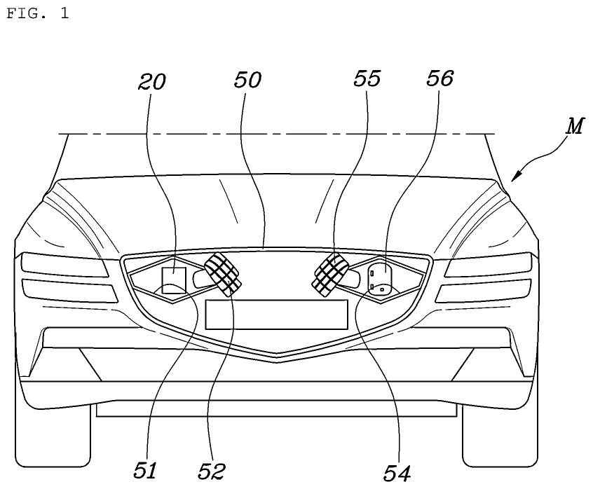

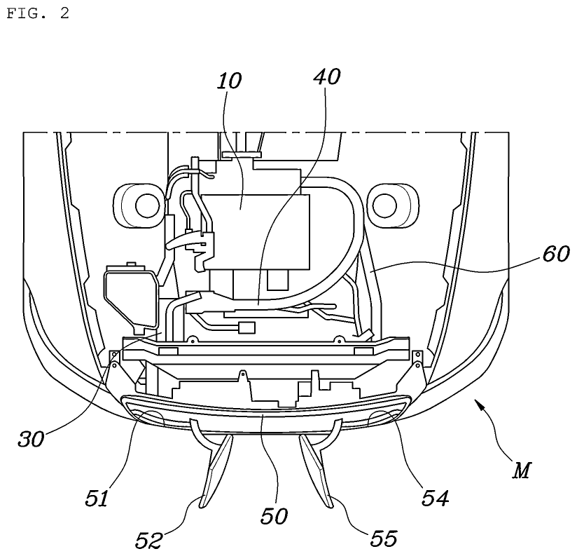

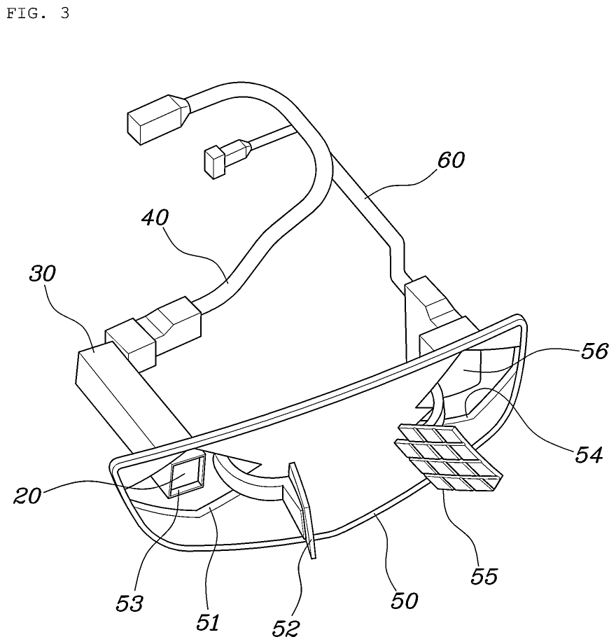

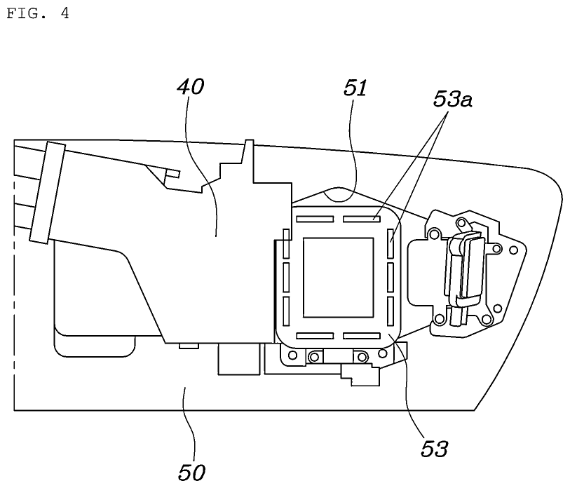

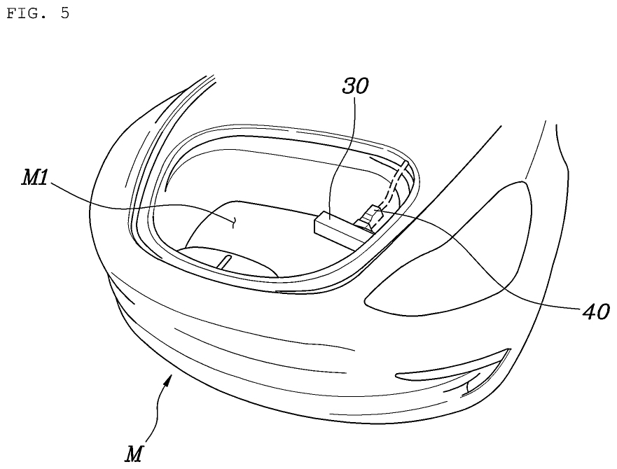

FIG. 1 is a view showing a front part of a mobility apparatus according to an embodiment of the present disclosure. FIG. 2 is a view showing an interior of the mobility apparatus shown in FIG. 1. FIG. 3 is a view showing a portable battery device for the mobility apparatus according to an embodiment of the present disclosure. FIG. 4 is a view showing a breakage inducing bracket in the portable battery device for the mobility apparatus shown in FIG. 3. FIG. 5 is a view showing a portable battery device for a mobility apparatus according to another embodiment of the present disclosure.

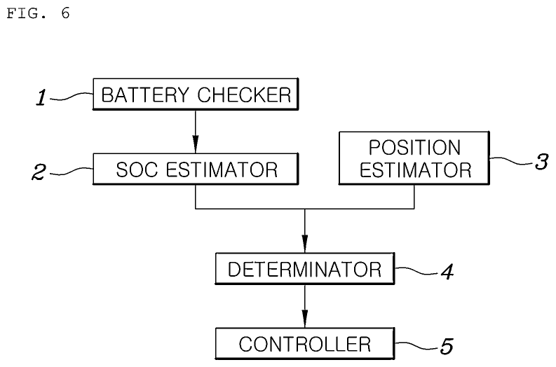

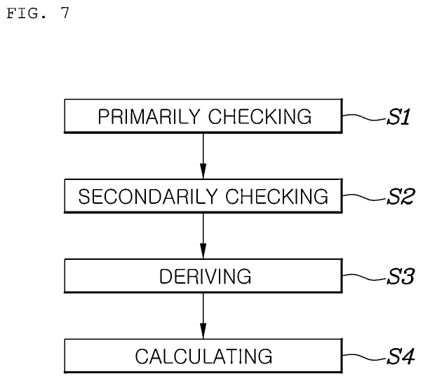

FIG. 6 is a block diagram of a battery management system according to an embodiment of the present disclosure. FIG. 7 is a flowchart of a battery management method according to an embodiment of the present disclosure.

As shown in FIGS. 1-4, the portable battery device for the mobility apparatus according to an embodiment of the present disclosure includes: a high-voltage battery 10 equipped in a mobility apparatus M; a case 30 provided in an inner space of the mobility apparatus M and formed to receive an auxiliary battery 20 therein such that the auxiliary battery 20 is cradled; and a first wiring 40 configured to electrically interconnect the high-voltage battery 10 and the auxiliary battery 20 received in the case 30.

The mobility apparatus M may be a motor-driven vehicle using electrical energy. A hybrid vehicle using an engine as a power source may be included as the vehicle.

The mobility apparatus M, as described above, is equipped with the high-voltage battery 10 for supply of electric power to electric parts and a motor. In accordance with a charging capacity of the high-voltage battery 10, a range of the mobility apparatus M is determined.

In accordance with an embodiment of the present disclosure, a desired range of the mobility apparatus M is secured through the auxiliary battery 20 capable of securing electric power in addition to the high-voltage battery 10.

When the auxiliary battery 20 is mounted in the case 30 equipped in the mobility apparatus M, the first wiring 40 is electrically connected to the auxiliary battery 20 and, as such, a range of the mobility apparatus M is increased in accordance with the addition of electric power from the auxiliary battery 20.

In addition, the auxiliary battery 20 is configured to be selectively mounted in the case 30 of the mobility apparatus M. Accordingly, when the mobility apparatus M can travel from a starting point to a destination point using the charged amount of the high-voltage battery 10, the mobility apparatus M may be reduced in weight through no mounting of the auxiliary battery 20. On the other hand, when the range of the mobility apparatus M is insufficient, this may be supplemented through mounting of the auxiliary battery 20.

The auxiliary battery 20 has a smaller size than that of the high-voltage battery 10 and, as such, the charging capacity thereof is small. However, since the auxiliary battery 20 is light and conveniently portable, it may be possible to secure a desired range of the mobility apparatus M through convenient mounting or separation of the auxiliary battery 20 to or from the mobility apparatus M.

The case 30 is provided in the inner space of the mobility apparatus M and is formed to receive the auxiliary battery 20 such that the auxiliary battery 20 is cradled.

The case 30 has a structure opened at one side for reception of the auxiliary battery 20. The case 30 is also formed to have a space matched with an outer shape of the auxiliary battery 20 and, as such, the auxiliary battery 20 received in the case 30 is fixed in position.

The first wiring 40 is connected to the case 30. The first wiring 40 is configured to be electrically connected to the auxiliary battery 20 received in the case 30. In addition, the first wiring 40 is electrically connected to the high-voltage battery 10 and, as such, electric power from the auxiliary battery 20 is supplied to the high-voltage battery 10 via the first wiring 40 when the auxiliary battery 20 is received in the case 30.

Through the above-described configuration, the mobility apparatus M, according to an embodiment of the present disclosure, may selectively supplement electric power in accordance with whether or not the auxiliary battery 20 is mounted. Therefore, a desired range of the mobility apparatus M may be selectively secured.

The embodiment of the present disclosure as described above is described in more detail with reference to FIG. 2. As shown in FIG. 2, the case 30 may be provided at the front part of the mobility apparatus M such that the case 30 is openable in inward and outward directions.

The mobility apparatus M is configured to easily secure a space at an inside of the front part thereof and, as such, may secure a space in which the case 30 may be installed.

There may not be space for mounting the auxiliary battery 20 at a side part of the mobility apparatus M. When the auxiliary battery 20 is mounted at a rear part of the mobility apparatus M, a trunk space should be used. In this case, accordingly, there is a problem in that the trunk space is reduced. On the other hand, a power system part for driving the mobility apparatus M is provided at the front part of the mobility apparatus M. Accordingly, it may be possible to easily secure an additional space for the case 30 in a space in which the power system part is provided.

The case 30 may be provided in the inner space of the front part of the mobility apparatus M and may be configured to be openable in inward and outward directions, for insertion and withdrawal of the auxiliary battery 20.

In particular, in accordance with an embodiment of the present disclosure, the case 30 may be installed at a guard 50 of the mobility apparatus M.

The guard 50 of the mobility apparatus M may be disposed at the front part of the mobility apparatus M. The guard 50 may be configured to cover at least one device including: a radiator part; a powertrain part; and a driving system part configured at the front part of the mobility apparatus M. The guard 50 may be formed to close the front part of the mobility apparatus M or may be formed to be opened in the form of a grill. As such, the guard 50 may be applied to the front part of the mobility apparatus M in various forms.

The guard 50 is configured at the front part of the mobility apparatus M. A first opening 51, which is open to the inner space of the mobility apparatus M, is formed at the guard 50. The case 30 is inserted into the guard 50 through the first opening 51, for installation thereof.

The case 30 is installed at the guard 50 as the case 30 is inserted through the first opening 51 opened in inward and outward directions and, as such, may be configured at the guard 50. In addition, when the case 30 is configured at the guard 50, as descried above, both the case 30 and the guard 50 are installed at the mobility apparatus M and, as such, easy assembly may be secured.

An isolation door 52, which selectively opens and closes the first opening 51 in accordance with a moved position thereof, is installed at the guard 50. The isolation door 52 is openable and closable.

The isolation door 52 may be rotatably installed at the guard 50 and may be formed to be matched with the first opening 51 for closing of the first opening 51. In addition, the isolation door 52 may be configured to be automatically opened and closed using a solenoid or a motor. However, the isolation door 52 may be configured to be opened through manual operation in an emergency situation in which electric power has been completely discharged, for insertion of the auxiliary battery 20.

As the first opening 51 of the guard 50 is closed by the isolation door 52, contamination of the case 30 and the auxiliary battery 20 is prevented. When installation of the auxiliary battery 20 is required, the isolation door 52 is opened, and the auxiliary battery 20 is inserted into the case 30 through the opened first opening 51. Therefore, supplement of electric power may be possible.

As shown in FIG. 4, a breakage inducing bracket 53, which is broken upon receiving external force higher than a critical value, is provided at the first opening 51 of the guard 50. The case 30 may be installed at the guard 50 by means of the breakage inducing bracket 53. In other words, the breakage inducing bracket 53 is used to install the case 30 at the guard 50.

The breakage inducing bracket 53 may be made of a material breakable upon receiving strong impact. The case 30 is installed at the first opening 51 of the guard 50 by means of the breakage inducing bracket 53. One side of the breakage inducing bracket 53 is installed at the first opening 51 of the guard 50. The case 30 is installed at the other side of the breakage inducing bracket 53. In addition, the breakage inducing bracket 53 may be formed to be open at a central portion thereof such that the auxiliary battery 20 may be inserted into the case 30 through the central portion.

When impact is applied to the mobility apparatus M, the breakage inducing bracket 53 is broken due to the impact and, as such, the case 30 is separated from the guard 50. Accordingly, the separated case 30 is separated from the mobility apparatus M, together with the auxiliary battery 20 and, as such, damage thereto caused by the impact may be prevented. In addition, since the auxiliary battery 20 is received in the case 30, the case 30 protects the auxiliary battery 20 and, as such, damage to the auxiliary battery 20 caused by impact directly applied to the auxiliary battery 20 may be prevented.

A plurality of breakage inducing slits 53a may be formed along an edge of the breakage inducing bracket 53 such that the breakage inducing slits 53a are uniformly spaced apart from one another.

As the breakage inducing slits 53a are formed at the breakage inducing bracket 53, breakage is induced at the breakage inducing bracket 53 when impact is applied to the mobility apparatus M. As a result, the case 30 and the auxiliary battery 20 may be separated from the guard 50. The number and shape of the breakage inducing slits 53a may be designed such that the breakage inducing slits 53a are broken upon receiving external force higher than a critical value previously derived through experiments.

A second opening 54 is also formed at the guard 50 such that the second opening 54 is open to the inner space of the mobility apparatus M while being spaced apart from the first opening 51. A second wiring 60 extending from the high-voltage battery 10 is installed at the second opening 54 of the guard 50.

In accordance with an embodiment of the present disclosure, it may be possible to achieve selective insertion or separation of the auxiliary battery 20 through the guard 50. It may also be possible to recharge the high-voltage battery 10 by interconnecting the second wiring 60 installed at the second opening 54 of the guard 50 and a charging port.

A charging connector 56, which is connectable to a charging port, may be provided at the second opening 54 of the guard 50. When the charging connector 56 is connected to an external charging port, the charging connector 56 receives electric power through the charging port and, as such, the electric power is supplied to the high-voltage battery 10 via the second wiring 60.

In particular, in the guard 50, the first opening 51, into which the auxiliary battery 20 is inserted, and the second opening 54, to which a charging port is connectable, are disposed to be spaced apart from each other. Therefore, electrical damage caused by a short circuit between a connection portion of the first wiring 40 at the first opening 51 and a connection portion of the second wiring 60 at the second opening 54 is prevented.

As the first opening 51 and the second opening 54 are disposed to be spaced apart from each other, electrical connection portions of the first wiring 40 and the second wiring 60 are spaced apart from each other and, as such, short circuit therebetween is prevented. In addition, the first wiring 40 and the second wiring 60 are configured such that insulated portions thereof, except for the electrical connection portions, are joined in the inner space of the mobility apparatus M. In accordance with such a configuration of the first wiring 40 and the second wiring 60, a wiring harness is configured. Thus, packaging of the first wiring 40 and the second wiring 60 may be achieved.

A charging door 55, which selectively opens and closes the second opening 54 in accordance with a moved position thereof, is installed at the guard 50. The charging door 55 is manually openable and closable.

The charging door 55 may be rotatably installed at the guard 50 and may be formed to be matched with the second opening 54 for closing of the second opening 54. In addition, the charging door 55 may be configured to be automatically opened and closed using a solenoid or a motor. However, the charging door 55 may be configured to be opened through manual operation in an emergency situation in which electric power has been completely discharged, for connection of a charging port.

As the second opening 54 of the guard 50 is closed by the charging door 55, the charging connector 56 may be protected from external contamination and impact.

In accordance with another embodiment of the present disclosure, as shown in FIG. 5, a reception space M1 may be configured at the front part of the mobility apparatus M, and the case 30 may be installed in the reception space M1.

When the mobility apparatus M is embodied as an electric vehicle, a front trunk (frunk), which is the reception space M1, may be configured at the front part of the mobility apparatus M. As the case 30 is installed in the frunk, which is the reception space M1 of the front part of the mobility apparatus M, the case 30 is prevented from interfering with other parts constituting the mobility apparatus M. In addition, when the reception space M1 is closed, both the case 30 and the auxiliary battery 20 may be protected from external contamination and impact.

As shown in FIG. 6, the battery management system according to an embodiment of the present disclosure includes: a battery checker 1 configured to check whether or not an auxiliary battery 20 has been mounted and to check a state of charge (SOC) of the auxiliary battery 20 when the auxiliary battery 20 has been mounted; an SOC estimator 2 configured to estimate an SOC of a high-voltage battery 10; a position estimator 3 configured to receive map information and to estimate a distance to a destination point set by the user; a determinator 4 configured to determine whether or not travel to the destination point identified through the position estimator 3 is possible in accordance with the SOC of the high-voltage battery 10 estimated through the SOC estimator 2; and a controller 5 configured to estimate an electric power amount required for travel to the destination point when the determinator 4 determines that travel to the destination point is impossible in accordance with the SOC of the high-voltage battery 10. The controller 5 is also configured to derive a number of auxiliary batteries 20 required in accordance with the required electric power amount.

The battery checker 1 checks whether or not an auxiliary battery 20 has been mounted and checks an SOC of the auxiliary battery 20 when the auxiliary battery 20 has been mounted.

In addition, the SOC estimator 2 estimates an SOC of a high-voltage battery 10 equipped in a mobility apparatus M.

Based on SOC information of the high-voltage battery 10 estimated by the SOC estimator 2, a range of the mobility apparatus M may be derived.

The position estimator 3 receives information as to a destination point set by the user and estimates a distance from a current point to the destination point, based on map information. The distance from the current point to the destination point is searched for, mainly in conjunction with a minimum distance, in order to minimize battery power consumption.

The determinator 4 collects information as to a range according to the SOC of the high-voltage battery 10 estimated by the SOC estimator 2 and information as to the distance to the destination point estimated by the position estimator 3 and, as such, determines whether or not travel to the destination point identified through the position estimator 3 is possible in accordance with the SOC of the high-voltage battery 10.

The controller 5 receives a determination value output from the determinator 4. Upon determining that travel to the destination point is possible in accordance with the SOC of the high-voltage battery 10, the controller 5 informs the driver of possibility of travel to the destination point. On the other hand, upon determining that travel to the destination point is impossible in accordance with the SOC of the high-voltage battery 10, the controller 5 calculates an electric power amount required for travel to the destination point, derives the number of auxiliary batteries 20 required in accordance with the calculated required electric power amount, and then informs the driver of the derived number of auxiliary batteries 20 required.

Accordingly, the driver may identify whether or not travel to the destination point is possible in the current state of the mobility apparatus M and may pre-store auxiliary batteries 20 to supplement an insufficient range so that stable travel to the destination point is possible.

As shown in FIG. 7, the battery management method of the above-described portable battery device for the mobility apparatus M according to an embodiment of the present disclosure includes: primarily checking a state of charge (SOC) of a high-voltage battery 10 (S1); secondarily checking an electric power consumption amount of the high-voltage battery 10 for travel from a start point to an arrival point, based on map information (S2); deriving an electric power amount required for travel to the arrival point when travel to the arrival point is impossible using the checked electric power consumption amount of the high-voltage battery 10 (S3); and calculating a required number of auxiliary batteries 20 in accordance with the derived required electric power amount (S4).

In the primarily checking act S1, an SOC of a high-voltage battery 10 is checked. In the secondarily checking act S2, an electric power consumption amount of the high-voltage battery 10 is calculated based on an arrival point set by the driver.

Upon determining that travel to the arrival point is impossible using the checked electric power consumption amount of the high-voltage battery 10, an electric power amount required for travel to the arrival point is derived through the deriving act S3.

Based on the required electric power amount derived in the deriving act S3, a required number of auxiliary batteries 20 satisfying the required electric power amount is calculated in the calculating act S4. Accordingly, the driver may pre-store the calculated auxiliary batteries 20 so that stable travel to the destination point is possible.

In addition, the secondarily checking act S2 may check information as to a position where supply of an auxiliary battery 20 is possible between the start point and the arrival point. The calculating act S4 may provide, to a passenger of the mobility apparatus M, the information as to the point (i.e., position) where supply of an auxiliary battery 20 is possible.

In the secondarily checking act S2, information as to a position where supply of an auxiliary battery 20 is possible between the start point and the arrival point set by the driver is checked based on map information. In the calculating act S4, information indicating that supply of an auxiliary battery 20 is possible at the position is provided in accordance with a required number of auxiliary batteries 20. In other words, when auxiliary batteries 20 are commercially available, the driver may receive an auxiliary battery 20 at a position where supply of the auxiliary battery 20 is possible, based on position information, during travel to an arrival point, without pre-storing the auxiliary battery 20. Thus, driver convenience is secured.

In the portable battery device for the mobility apparatus M and the battery management system and the method configured as described above, it may be possible to secure a desired range of the mobility apparatus M by selectively adding an auxiliary battery 20 in a situation in which a battery capacity should be additionally supplemented, for example, an emergency situation, a range required situation, or the like.

In addition, the auxiliary battery 20 may be stored in the mobility apparatus M or may be supplied from an external supply source when the auxiliary battery 20 is commercially available. Accordingly, electric power supply to the mobility apparatus M becomes convenient.

Furthermore, the auxiliary battery 20 is simply replaceable through separation or mounting thereof from or in the case 30 at an outside of the mobility apparatus M. Accordingly, handling convenience of the auxiliary battery 20 is enhanced.

In addition, when collision of the mobility apparatus M occurs, the auxiliary battery 20 is separated due to impact and, as such, generation of fire caused by damage to the auxiliary battery 20 is prevented. Thus, stability is secured.

Although embodiments of the present disclosure have been disclosed for illustrative purposes, those having ordinary skill in the art should appreciate that various modifications, additions and substitutions are possible, without departing from the scope and spirit of the disclosure as disclosed in the accompanying claims.

What is claimed is:

1. A portable battery device for a mobility apparatus, the portable battery device comprising:
a high-voltage battery equipped in the mobility apparatus;
a case provided in an inner space of the mobility apparatus and formed to receive an auxiliary battery therein, such that the auxiliary battery is cradled; and
a first wiring configured to electrically interconnect the high-voltage battery and the auxiliary battery received in the case.

2. The portable battery device according to claim 1, wherein the case is installed in an inner space of a front part of the mobility apparatus.

3. The portable battery device according to claim 1, wherein a guard is configured at a front part of the mobility apparatus, a first opening open to the inner space of the mobility apparatus is formed at the guard, and the case is configured to be installed by being inserted into the guard through the first opening.

4. The portable battery device according to claim 3, wherein an isolation door selectively opening and closing the first opening in accordance with a moved position thereof is installed at the guard.

5. The portable battery device according to claim 3, wherein a breakage inducing bracket configured to be broken upon receiving external force higher than a critical value is provided at the first opening of the guard, and the case is installed at the guard by the breakage inducing bracket.

6. The portable battery device according to claim 5, wherein a plurality of breakage inducing slits is formed along an edge of the breakage inducing bracket such that the breakage inducing slits are uniformly spaced apart from one another.

7. The portable battery device according to claim 3, wherein a second opening is formed at the guard such that the second opening is open to the inner space of the mobility apparatus while being spaced apart from the first opening, and a second wiring extending from the high-voltage battery is installed at the second opening of the guard.

8. The portable battery device according to claim 7, wherein a charging door selectively opening and closing the second opening in accordance with a moved position thereof is installed at the guard, and the charging door is manually openable and closable.

9. The portable battery device according to claim 1, wherein a reception space is configured at a front part of the mobility apparatus, and the case is installed in the reception space.

10. A battery management system for a mobility apparatus, the battery management system comprising:
a battery checker configured to check whether or not an auxiliary battery has been mounted and to check a state of charge (SOC) of the auxiliary battery when the auxiliary battery has been mounted;
a SOC estimator configured to estimate a SOC of a high-voltage battery;
a position estimator configured to receive map information and to estimate a distance to a destination point set by a user;
a determinator configured to determine whether or not travel to the destination point identified through the position estimator is possible in accordance with the SOC of the high-voltage battery estimated through the SOC estimator; and
a controller configured to estimate an electric power amount required for travel to the destination point when the determinator determines that travel to the destination point is impossible in accordance with the SOC of the high-voltage battery, and to derive a number of auxiliary batteries required in accordance with the required electric power amount.

11. A battery management method for a mobility apparatus, the battery management method comprising:
primarily checking a state of charge (SOC) of a high-voltage battery;
secondarily checking an electric power consumption amount of the high-voltage battery for travel from a start point to an arrival point, based on map information;
deriving an electric power amount required for travel to the arrival point when travel to the arrival point is impossible using the checked electric power consumption amount of the high-voltage battery; and
calculating a required number of auxiliary batteries in accordance with the derived required electric power amount.

12. The battery management method according to claim 11, wherein:
the secondarily checking checks information as to a position where supply of an auxiliary battery is possible between the start point and the arrival point; and
the calculating provides, to a passenger of the mobility apparatus, the information as to the position where supply of the auxiliary battery is possible.
